(19) United States
(12) Patent Application Publication
(10) Pub. No.: US 2026/0277169 A1
(43) Pub. Date: Sep. 17, 2026

(54) Safety Interlock Control System and Safety Interlock Control Method

(71) Applicant: Samsung Electronics Co., Ltd., Suwon-si (KR)

(72) Inventors: Dongjoon Myung, Suwon-si (KR); Hyunmin Cho, Suwon-si (KR); Dongsoo Jo, Suwon-si (KR); Seungho Sim, Suwon-si (KR); Jaemin Kim, Suwon-si (KR); Changsoo Lee, Suwon-si (KR); Sangho Roh, Suwon-si (KR)

(21) Appl. No.: 19/464,301

(22) Filed: Jan. 29, 2026

(30) Foreign Application Priority Data
Mar. 11, 2025 (KR) 10-2025-0031723
Jun. 4, 2025 (KR) 10-2025-0073008

(51) Int. Cl. G05B 9/02; H10P 72/00

(52) U.S. Cl. CPC G05B 9/02; H10P 72/06

(57) ABSTRACT

A safety interlock control system includes a user interface configured to receive input data including data in a form of natural language, an interlock manager configured to perform a text mining algorithm on the input data to determine a facility operation corresponding to the input data, and to derive a list of interlocks corresponding to the determined facility operation and compare the derived list of interlocks to a predefined list of standard interlocks to warn the user of a list of bypassed selective safety interlocks that are not activated. The interlock manager includes an interlock matcher configured to match the standard interlocks to the list of selective safety interlocks corresponding to the input data, and an interlock event analyzer configured to identify whether the matched list of selective safety interlocks is activated.

### CROSS-REFERENCE TO RELATED APPLICATIONS

This application is based on and claims priority under 35 U.S.C. §119 to Korean Patent Application Nos. 10-2025-0031723, filed on Mar. 11, 2025, and 10-2025-0073008, filed on Jun. 04, 2025, in the Korean Intellectual Property Office, the disclosures of each of which are incorporated by reference herein in their entirety.

### BACKGROUND

As the degree of integration of semiconductor devices increases, semiconductor manufacturing processes are becoming increasingly specialized and complicated. In particular, with the increasing use of equipment for processes involving high temperatures, high voltages, and harmful chemicals, such as etching, deposition, ion implantation, and cleaning, ensuring operator safety has become an important issue.

### SUMMARY

The present disclosure relates to a safety interlock control system and a safety interlock control method, and more particularly, to a safety interlock control system using machine learning and a safety interlock control method.

Aspects of the present disclosure provide a safety interlock control system having improved reliability and a safety interlock control method.

Also, the objective of the present disclosure is not limited to that stated above, and other objectives are clearly understood by those skilled in the art from the following description.

According to an aspect of the present disclosure, there is provided a safety interlock control system including a user interface configured to receive, from a user, input data comprising data in a form of natural language and to transmit a response to the user; and an interlock manager configured to perform a text mining algorithm on the input data to derive a list of selective safety interlocks corresponding to the input data, and to transmit a warning to the user about a list of bypassed selective safety interlocks that are not activated, wherein the interlock manager comprises: an interlock matcher configured to match the list of selective safety interlocks corresponding to the input data; an interlock event analyzer configured to identify whether the matched list of selective safety interlocks is activated; and an interlock result integrator configured to transmit, to the user, the list of bypassed selective safety interlocks that are not activated, via the user interface.

According to another aspect of the present disclosure, there is provided a safety interlock control system including a user interface configured to receive, from a user, input data comprising data in a form of natural language and to transmit a response to the user; and an interlock manager configured to perform a text mining algorithm on the input data to derive a list of selective safety interlocks corresponding to the input data, identify whether the list of selective safety interlocks is activated, and transmit a warning to the user about a list of bypassed selective safety interlocks that are not activated, wherein the interlock manager comprises: a log analyzer configured to match a facility operation corresponding to the input data; an interlock matcher configured to match the list of selective safety interlocks corresponding to the facility operation; an interlock event analyzer configured to identify whether the matched list of selective safety interlocks is activated; and an interlock result integrator configured to transmit, to the user, the list of bypassed selective safety interlocks that are not activated, via the user interface.

According to another aspect of the present disclosure, there is provided a safety interlock control system including a user interface configured to receive, from a user, input data comprising data in a form of natural language and to transmit a response to the user; an interlock manager configured to perform a text mining algorithm on the input data to derive a list of selective safety interlocks corresponding to the input data, identify whether the list of selective safety interlocks is activated, and transmit a warning to the user about a list of bypassed selective safety interlocks that are not activated; and a statistical analyzer configured to infer a safety interlock bypass pattern based on the input data and the list of bypassed selective safety interlocks, wherein the interlock manager comprises: a log analyzer configured to match a semiconductor facility operation corresponding to the input data; an interlock matcher configured to match the list of selective safety interlocks corresponding to the semiconductor facility operation and required to be activated; an interlock event analyzer configured to identify whether the matched list of selective safety interlocks is activated; and an interlock result integrator configured to transmit, to the user, the list of bypassed selective safety interlocks that are not activated, via the user interface, and wherein the log analyzer comprises: a pre-processor configured to pre-process the input data; a feature extractor configured to extract features from the pre-processed input data; and an analyzer configured to determine a facility operation corresponding to the input data based on the extracted features, and wherein the interlock event analyzer is configured to determine whether the selective safety interlock is activated based on sensing data from a main sensor configured to directly identify whether a safety interlock of a semiconductor facility is activated, and wherein the interlock result integrator is configured to: transmit a warning to the user about the list of bypassed selective safety interlocks via the user interface; and store the list of bypassed selective safety interlocks and the input data corresponding to the list of bypassed selective safety interlocks in a database.

### BRIEF DESCRIPTION OF THE DRAWINGS

Implementations will be more clearly understood from the following detailed description taken in conjunction with the accompanying drawings in which:

FIG. 1 is a schematic layout diagram showing a semiconductor process system including a safety interlock control system according to an implementation;

FIG. 2 is a schematic layout diagram showing the configuration of a safety interlock control system according to an implementation;

FIG. 3 is a schematic layout diagram showing the configuration of a log analysis unit according to an implementation;

FIG. 4 is a schematic layout diagram showing an analysis unit and a facility operation DB according to an implementation;

FIG. 5 is a schematic layout diagram showing an interlock matching unit and a standard interlock DB according to an implementation;

FIG. 6 is a schematic layout diagram showing an operation of an interlock event analysis unit according to an implementation;

FIG. 7 is a schematic layout diagram showing the configuration of a safety interlock control system according to an implementation;

FIG. 8 is a block diagram showing the configuration of a monitoring unit according to an implementation;

FIG. 9 is a flowchart illustrating a safety interlock control method according to an implementation;

FIG. 10 is a flowchart showing a method of deriving a list of selective safety interlocks to be activated, according to an implementation;

FIG. 11 is a flowchart showing a method of deriving a list of selective safety interlocks to be activated, according to an implementation; and

FIG. 12 is a block diagram showing a safety interlock control system according to an implementation.

### DETAILED DESCRIPTION

Hereinafter, implementations are described in detail with reference to the accompanying drawings. The same reference numerals are given to the same elements in the drawings, and repeated descriptions thereof are omitted. In the following drawings, the thickness and size of each layer are exaggerated for convenience and clarity of description, and may be slightly different from the actual shape and proportions thereof.

As discussed above, with the increasing use of equipment for processes involving high temperatures, high voltages, and harmful chemicals, such as etching, deposition, ion implantation, and cleaning, ensuring operator safety has become an important issue. Accordingly, safety interlock systems may be introduced in various types of equipment in order to prevent accidents by restricting operator access to equipment or controlling equipment operation in the event of malfunction or abnormal conditions. Aspects of the present disclosure may address these issues in the related art.

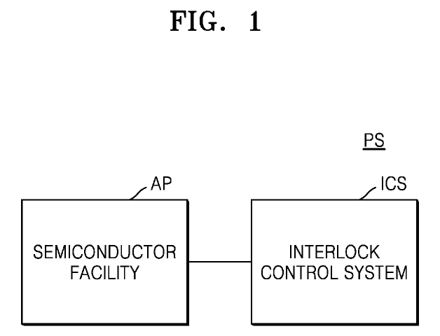

FIG. 1 is a schematic layout diagram showing a semiconductor process system including a safety interlock control system according to an implementation.

Referring to FIG. 1, a semiconductor process system PS may perform various processes for manufacturing semiconductor devices. Also, the semiconductor process system PS may include a plurality of semiconductor facilities AP and a safety interlock control system ICS for safely operating the plurality of semiconductor facilities AP.

The plurality of semiconductor facilities AP may perform a semiconductor process on a semiconductor substrate. In an implementation, the plurality of semiconductor facilities AP may include a wafer processing device, an inspection device, a transfer device, and/or a utility device.

For example, the wafer processing device may include an etching device, a deposition device, a cleaning device, a heat treatment device, an ion implantation device, a lithography device, and/or a chemical mechanical polishing (CMP) device. For example, the inspection device may include a measurement device, a defect inspection device, and/or an electrical test device. For example, the transfer device may include a wafer transfer robot and/or a load port. For example, the utility device may include a gas supply device, a chemical solution supply device, a cooling water supply device, a power supply device, and/or an exhaust device. However, devices provided in the semiconductor facilities AP are not limited thereto, and the semiconductor facilities AP may include various types of devices.

The safety interlock control system ICS may be configured to inspect whether safety interlocks of the plurality of semiconductor facilities AP are activated. Herein, the safety interlock may represent a mechanism that controls (e.g., suspends) an operation of the semiconductor facility AP when the semiconductor facility AP is not in a normal state. In an implementation, the safety interlock control system ICS according to the present disclosure may inspect whether a preset safety interlock operates properly. In particular, the safety interlock control system ICS according to the present disclosure may inspect whether an interlock system operates properly after maintenance/repair of the semiconductor facility AP. Also, the safety interlock control system ICS according to the present disclosure may issue a warning to a user about a list of bypassed selective safety interlocks.

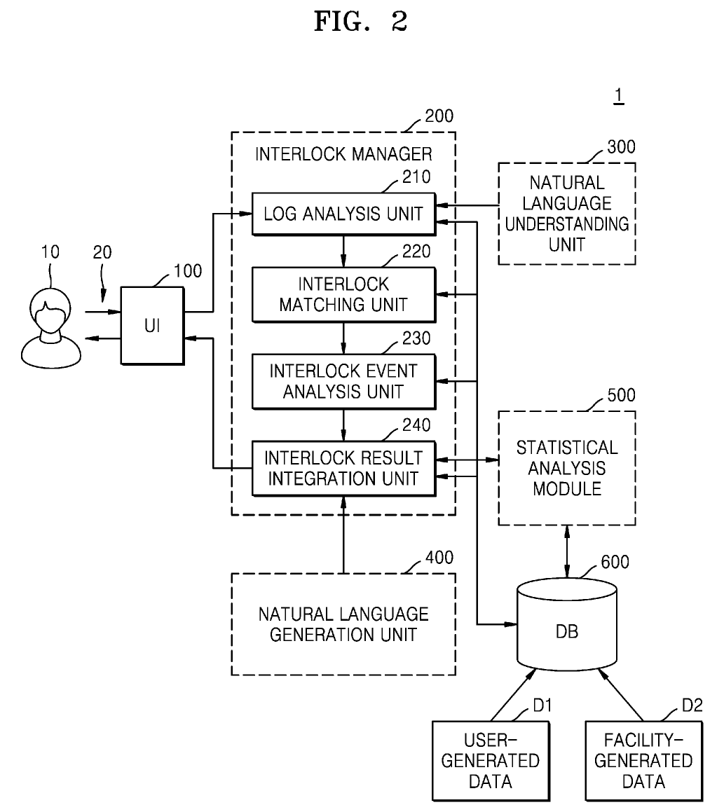

The configuration of the safety interlock control system ICS is described in detail with reference to FIGS. 2 - 8.

FIG. 2 is a schematic layout diagram showing the configuration of a safety interlock control system according to an implementation. A description is given below with reference to FIG. 1.

Referring to FIG. 2, a safety interlock control system 1 may include a user interface (UI) 100 that receives data from a user 10 via a network 20 and transmits a response thereto. The network 20 may include all devices that may exchange data via wired/wireless communications, such as a wired Internet service, a local area network (LAN), a wide area network (WAN), Intranet, a wireless Internet service, a mobile computing service, a wireless data communication service, a wireless Internet access service, a satellite communication service, a wireless LAN, and Bluetooth. When the network 20 is connected to a smartphone or tablet, etc., the network 20 may include wireless data communication services such as 3G, 4G, and 5G, wireless LAN such as Wi-Fi, Bluetooth, etc.

The safety interlock control system 1 according to the present disclosure may receive input data from the user 10 and output a list of selective safety interlocks to be activated, and identify whether the safety interlocks in the list are activated. In some implementations, an interlock result integration unit 240 of the safety interlock control system 1 may inform the user 10 and/or a higher-level module of the list of bypassed selective safety interlocks (i.e., the list of safety interlocks that should be activated but are not activated) and issue a corresponding warning. For example, the higher-level module may include the safety interlock control system 1 and/or the semiconductor process system PS. In an implementation, the safety interlock control system 1 may execute the list of bypassed selective safety interlocks. As used herein, the term "list of selective safety interlocks" may represent a list of safety interlocks that correspond to specific facility operations among the safety interlocks.

The safety interlock control system 1 according to the present disclosure may receive log data from the semiconductor facility AP. The input data may include log data created by the user 10, facility change management data, and/or log data from the semiconductor facility AP. In an implementation, the log data (e.g., facility operation and facility change management data) created by the user 10 may have a natural language form. In an implementation, the log data of the semiconductor facility AP may have a natural language form and/or a non-natural language form.

As used herein, the term "facility change management data" may represent a list of essential items that should be checked before and after the maintenance of semiconductor facilities AP. For example, the facility change management data may include item identifiers, objects to be inspected, allowable range (or reference values), inspection methods, verification methods, and/or verification times.

The UI 100 may provide an interface for accessing the safety interlock control system 1, via a terminal, etc., used by the user 10. The user 10 may transmit data to the safety interlock control system 1 via the UI 100, and may receive whether or not interlock has occurred with respect to data provided by the safety interlock control system 1 via the UI 100.

The safety interlock control system 1 may include an interlock manager 200 that is connected to the UI 100, receives input data from a database (DB) 600, determines an output, and transmits the output to the user 10 via the UI 100. Also, components in the safety interlock control system 1 may be controlled by the interlock manager 200.

The safety interlock control system 1 may include a natural language understanding unit 300 that analyzes input data in the form of natural language received by the interlock manager 200.

As used herein, the term "output" may represent a result provided by the safety interlock control system 1 in response to the input data provided by the user 10, such as a list of selective safety interlocks to be activated in response to the input data and/or whether the list of selective safety interlocks has been executed. Finally, the "output" may include whether the selective safety interlocks have been activated and/or the list of bypassed selective safety interlocks.

The safety interlock control system 1 may further include a natural language generation unit 400, and thus, the safety interlock control system 1 may provide the user 10 with a response in the form of natural language.

For example, with respect to the input data in the form of natural language, the safety interlock control system 1 may analyze the input data in a log analysis unit 210 with reference to the natural language understanding unit 300. In this process, the input data in the form of non-natural language may be referenced. Also, in the safety interlock control system 1, the interlock manager 200 may generate an output in the form of natural language from the analyzed input data with the aid of the natural language generation unit 400 and then provide the output to the user 10.

The interlock manager 200 may include a log analysis unit 210, an interlock matching unit 220, an interlock event analysis unit 230, and an interlock result integration unit 240. The log analysis unit 210 may perform natural language analysis on input data (e.g., log data) from the user 10 with reference to the natural language understanding unit 300. The log analysis unit 210 may analyze the maintenance history about equipment of the semiconductor facility AP on the basis of the input data from the user 10.

In an implementation, the natural language understanding unit 300 may perform, on the input data, a plurality of unit analysis processes, such as semantic role labeling, morphological analysis, syntactic analysis, named entity analysis, filtering analysis, intent classification, and domain analysis. Some of the plurality of unit analysis processes may be performed in parallel. Some of the plurality of unit analysis processes may be performed in sequence.

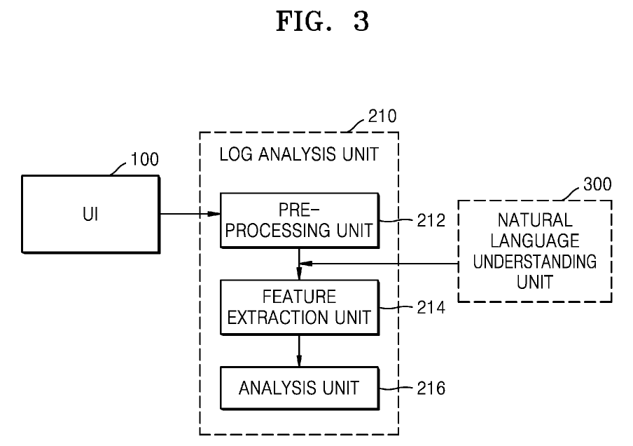

The log analysis unit 210 may generate natural language analysis results on the input data by the natural language understanding unit 300 performing at least some of the plurality of unit analysis processes, such as semantic role labeling, morphological analysis, syntactic analysis, named entity analysis, filtering analysis, intent classification, and domain analysis. In some implementations, the log analysis unit 210 may transmit the natural language analysis results for the input data to the interlock matching unit 220. The configuration of the log analysis unit 210 is described with reference to FIG. 3.

FIG. 3 is a schematic layout showing the configuration of a log analysis unit according to an implementation. A description is given below with reference to FIG. 2.

Referring to FIG. 3, the log analysis unit 210 may include a pre-processing unit 212, a feature extraction unit 214, and an analysis unit 216. In an implementation, the log analysis unit 210 may analyze data received from the user 10, by using a text mining algorithm. The text mining algorithm may represent an algorithm that extracts meaningful information from unstructured text data. More specifically, the text mining algorithm may extract features from text and derive classification, clustering, and association rules based on the features.

The pre-processing unit 212 may perform pre-processing on the input data received by the log analysis unit 210. In an implementation, the pre-processing unit 212 may perform tokenization, stop-word removal, stemming, and/or normalization on the input data. Herein, the tokenization may represent dividing the input data into words and/or morphemes. Also, the stop-word removal may represent filtering out words that have no meaning (e.g., articles, conjunctions, etc.). In some implementations, the stemming and the normalization may represent unifying forms of data.

The natural language understanding unit 300 may convert text into structured information with respect to the input data pre-processed by the pre-processing unit 212. As described above, the natural language analysis results on the input data may be generated by the natural language understanding unit 300 performing at least some of the plurality of unit analysis processes, such as semantic role labeling, morphological analysis, syntactic analysis, named entity analysis, filtering analysis, intent classification, and domain analysis.

The feature extraction unit 214 may extract features from the input data converted by the natural language understanding unit 300. In an implementation, the feature extraction unit 214 may embed the input data based on deep learning. For example, the feature extraction unit 214 may extract features by using a pre-trained language model. For example, the language model may include a transformer-based language model. However, the present disclosure is not limited thereto, and the language model may include various types of language models. In another implementation, the feature extraction unit 214 may extract features by generating a word frequency-based sparse vector, or may extract features on the basis of a distributed representation-based embedding technique (e.g., word2vec, glove, fasttext, etc.).

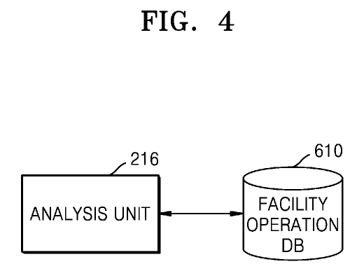

The analysis unit 216 may determine a facility operation corresponding to the input data that is input by the user 10 based on the features extracted by the feature extraction unit 214. The analysis unit 216 may determine the facility operation corresponding to the input data with reference to first input data in the form of natural language and/or second input data in the form of non-natural language. The analysis unit 216 is described with reference to FIG. 4.

FIG. 4 is a schematic layout diagram showing an analysis unit and a facility operation DB according to an implementation. A description is given below with reference to FIG. 2.

Referring to FIG. 4, the analysis unit 216 may determine the facility operation corresponding to the input data in a rule-based method. In an implementation, the analysis unit 216 may communicate with a facility operation DB 610 and determine a facility operation corresponding to the input data. For example, the facility operation may include regular maintenance (predictive maintenance (PM)), irregular maintenance (breakdown maintenance (BM)), facility inspections, process evaluations, and replacement of components in a specific semiconductor facility AP.

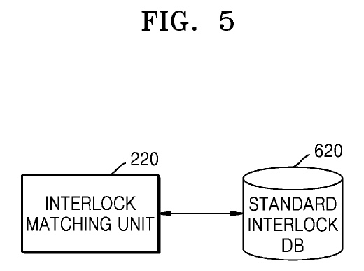

Referring back to FIG. 2, with respect to a corresponding facility operation in the log analysis unit 210, the interlock matching unit 220 may be configured to match the list of safety interlocks associated with the facility operation. The interlock matching unit 220 is described with reference to FIG. 5.

FIG. 5 is a schematic layout diagram showing an interlock matching unit and a standard interlock DB according to an implementation. A description is given below with reference to FIG. 2.

In an implementation, based on a list of standard interlocks, the interlock matching unit 220 may be configured to match the list of safety interlocks associated with the facility operation (i.e., derive the list of selective safety interlocks that are required to be operated for the corresponding operation). Herein, the list of standard interlocks may represent a set of safety interlocks corresponding to the facility operation. The interlock matching unit 220 may match the list of standard interlocks in a rule-based method.

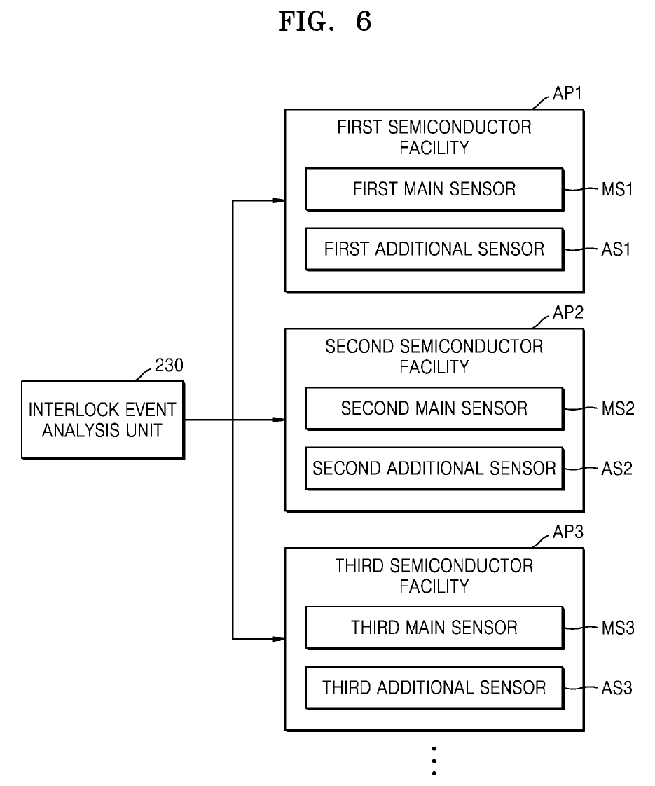

Referring back to FIG. 2, the interlock event analysis unit 230 may determine whether one or more selective safety interlocks matched in the interlock matching unit 220 have been performed. The interlock event analysis unit 230 is described with reference to FIG. 6.

FIG. 6 is a schematic layout diagram showing an operation of an interlock event analysis unit according to an implementation.

Referring to FIG. 6, the interlock event analysis unit 230 may be connected to a plurality of sensors of the semiconductor facility AP via a network and may receive the plurality of pieces of sensor data. The interlock event analysis unit 230 may determine, based on the received pieces of sensor data, whether the safety interlock has been performed. The interlock event analysis unit 230 may determine a list of selective safety interlocks that are not activated from among the list of selective safety interlocks that are to be activated. For example, the interlock event analysis unit 230 may determine the list of bypassed selective safety interlocks.

The sensors in the semiconductor facility AP may include a main sensor and an additional sensor. The main sensor may include a safety interlock sensor that may directly determine whether the safety interlock has been performed. For example, when the safety interlock relates to opening and closing of a chamber door, the main sensor of the safety interlock may include a sensor that determines whether the chamber door is open or closed. The additional sensor may include a sensor that may indirectly determine whether the safety interlock has been performed. In some implementations, although the main purpose of the additional sensor is to manage process quality, the additional sensor may also provide data for assisting the safety interlock. For example, when the safety interlock relates to the opening and closing of the chamber door, the additional sensor of the safety interlock may include a pressure sensor, a temperature sensor, a voltage sensor, and/or a flow rate sensor inside the chamber. Changes in pressure or temperature inside the chamber may be sensed by the additional sensor and used as additional sensor data for the safety interlock.

FIG. 6 shows an example in which the interlock event analysis unit 230 is connected to three semiconductor facilities AP, but the present disclosure is not limited thereto. For example, the interlock event analysis unit 230 may be connected to a first semiconductor facility AP1, a second semiconductor facility AP2, and a third semiconductor facility AP3. The first semiconductor facility AP1 may include a first main sensor MS1 and a first additional sensor AS1, the second semiconductor facility AP2 may include a second main sensor MS2 and a second additional sensor AS2, and a third semiconductor facility AP3 may include a third main sensor MS3 and a third additional sensor AS3. The main sensor and/or the additional sensor may each be provided in plurality.

The interlock event analysis unit 230 may determine whether the safety interlock has been performed, based on the sensing data from each of the main sensor and/or the additional sensor. When the sensing data of each of the main sensor and/or the additional sensor is within a preset range, the interlock event analysis unit 230 may determine that the safety interlock has been performed. On the contrary, when the sensing data of each of the main sensor and/or the additional sensor is outside the preset range, the interlock event analysis unit 230 may determine that the safety interlock has not been performed.

In an implementation, the interlock event analysis unit 230 may determine whether to perform the safety interlock, based on first sensing data from the main sensor and second sensing data from the additional sensor. For example, whether the safety interlock corresponding to the main sensor is performed may be determined depending on whether the first sensing data is executed. In another example, even if the first sensing data is normal, when the second sensing data is in an abnormal range, the interlock event analysis unit 230 may determine that the safety interlock has not been performed. Therefore, even if the main sensor is defective, the interlock event analysis unit 230 may accurately determine whether the safety interlock is performed. In some implementations, as used herein, the term “normal range” may refer to a predefined range of sensor values that may indicate expected or safe operating conditions for a semiconductor facility. The term “abnormal range” may refer to sensor values that fall outside the predefined normal range and may indicate a malfunction or unsafe condition.

The interlock result integration unit 240 may generate an output in the form of natural language with reference to the natural language generation unit 400 based on the data analyzed by the interlock event analysis unit 230, and may then provide the output to the user 10. The output data generated by the interlock result integration unit 240 may be provided to the user 10 via the UI 100.

The interlock result integration unit 240 may inform the user 10 of the list of selective safety interlocks that are not activated among the list of selective safety interlocks that should be activated, and may then issue a warning. For example, the interlock result integration unit 240 may inform the user 10 of the list of bypassed selective safety interlocks and issue a warning. In an implementation, the interlock result integration unit 240 may be configured to execute the list of bypassed selective safety interlocks. The interlock result integration unit 240 may generate an output in the form of natural language, with reference to the natural language generation unit 400.

A statistical analysis module 500 may communicate with the DB 600 and infer interlock bypass patterns occurring at a specific semiconductor facility AP and/or a specific operation (e.g., a maintenance operation). The statistical analysis module 500 may be configured to infer relationships between input data and output data. Therefore, the statistical analysis module 500 may be configured to predict the output data based on the input data.

In an implementation, the statistical analysis module 500 may infer, based on a machine learning algorithm, the interlock bypass patterns that occur in the specific semiconductor facility AP and/or the specific operation (e.g., the maintenance operation). For example, the statistical analysis module 500 may include a model that is trained via supervised learning.

The safety interlock control system 1 may further include the DB 600 that may communicate with the interlock manager 200, the natural language understanding unit 300, the natural language generation unit 400, and/or the statistical analysis module 500 via the network 20. The DB 600 may be configured to store big data. The DB 600 may store data of the interlock manager 200. In one implementation, the DB 600 may store data of each of the log analysis unit 210, the interlock matching unit 220, the interlock event analysis unit 230, and/or the interlock result integration unit 240. Also, the DB 600 may store data that is input to and/or output from the UI 100. In some implementations, the DB 600 may store data generated by the semiconductor facilities AP (e.g., sensing data from each of the main sensor and/or the additional sensor, and facility log data). In other words, the DB 600 may store user-generated data D1 and/or facility-generated data D2. The user-generated data D1 may include facility operation logs and facility change management log data, and the facility-generated data D2 may include facility log data.

The safety interlock control system 1 may determine in real time whether the selective interlock has been bypassed. Also, the safety interlock control system 1 may provide the user 10 in real time with whether or not the selective safety interlock has been bypassed, and may issue a warning. Therefore, the reliability of the semiconductor process system PS including the safety interlock control system 1 may be improved.

The safety interlock control system 1 according to the present disclosure may derive a list of selective safety interlocks to be activated, based on the operation log data of the semiconductor facility AP of the user, the change management data of the semiconductor facility AP, and/or the log data of the semiconductor facility AP, and may identify whether the list of selective safety interlocks has been activated. In particular, the safety interlock control system 1 according to the present disclosure may accurately determine the list of selective safety interlocks to be activated by using a text mining technique for the log data. Therefore, the stability of semiconductor processes may be improved, and the reliability of a semiconductor process system including the safety interlock may be improved.

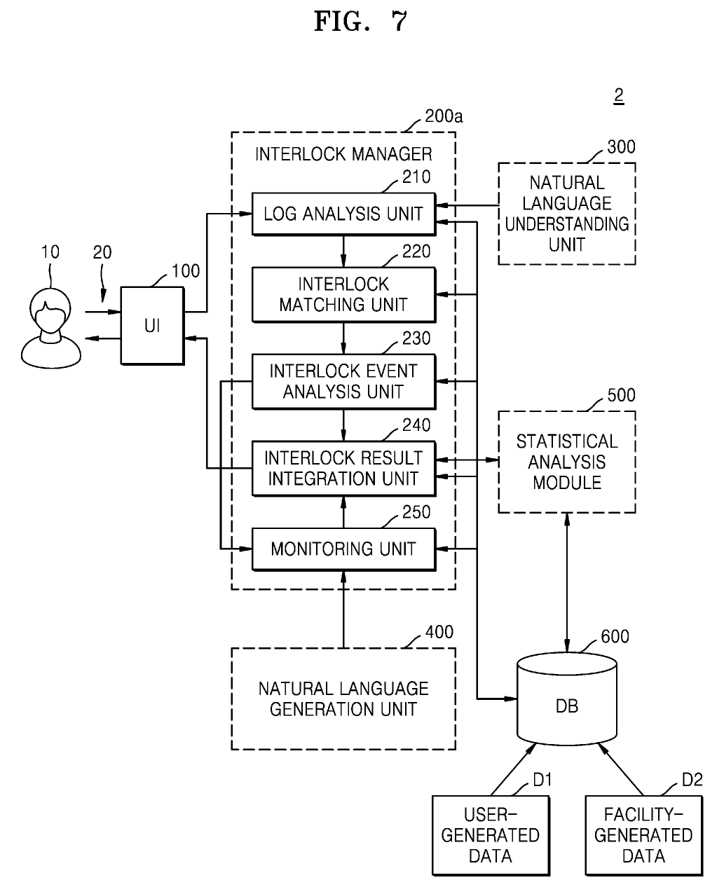

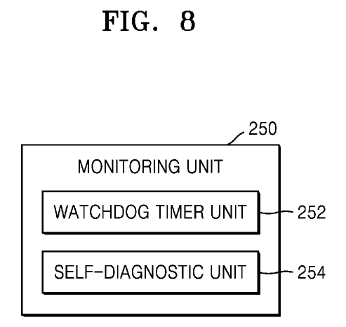

FIG. 7 is a schematic layout diagram showing the configuration of a safety interlock control system according to an implementation. FIG. 8 is a block diagram showing the configuration of a monitoring unit according to an implementation. A description is given below with reference to FIGS. 1 to 6.

A safety interlock control system 2 in FIG. 7 may be substantially the same as the safety interlock control system 1 in FIG. 2, except that the safety interlock control system 2 may further include a monitoring unit 250. Therefore, the description focuses on the monitoring unit 250.

Referring to FIGS. 7 and 8, the safety interlock control system 2 may include an interlock manager 200a that may include the log analysis unit 210, the interlock matching unit 220, the interlock event analysis unit 230, the interlock result integration unit 240, and the monitoring unit 250. The monitoring unit 250 may include a watchdog timer unit 252 and a self-diagnostic unit 254. The monitoring unit 250 may be configured to determine whether the safety interlock is normal or defective. In some implementations, as used herein, the term “normal” in reference to a safety interlock may indicate that the safety interlock is functioning as intended, such that the relevant sensor data falls within a predefined acceptable range and the interlock mechanism is properly engaged. The term “abnormal” or “defective” in reference to a safety interlock may refer to a condition in which the safety interlock is not functioning as intended, such as when sensor data falls outside the acceptable range, the interlock mechanism fails to engage, or the system detects a bypass or malfunction.

When there is a safety interlock that has not been activated for a certain period of time, the watchdog timer unit 252 may activate the safety interlock to test the safety interlock. The certain period of time may represent a preset period of time. Therefore, the watchdog timer unit 252 may easily determine whether the safety interlock is defective.

As described above, the watchdog timer unit 252 may determine whether the safety interlock is normal or abnormal based on the sensing data from each of the main sensor and/or the additional sensor connected to the safety interlock.

The self-diagnostic unit 254 may be configured to perform self-diagnostics on the safety interlock control system 2. The self-diagnostic unit 254 may determine whether the safety interlock control system 2 may include a defect by using logic. In an implementation, when the safety interlock system may include an unresolved problem for a certain period of time, the self-diagnostic unit 254 may determine that the safety interlock system is defective. Also, the self-diagnostic unit 254 may be configured to identify unresolved problems in the safety interlock system and to resolve the problems.

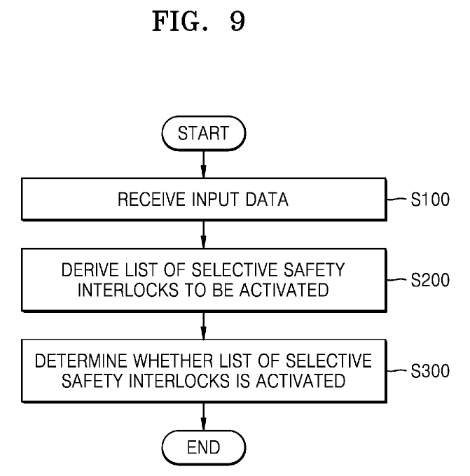

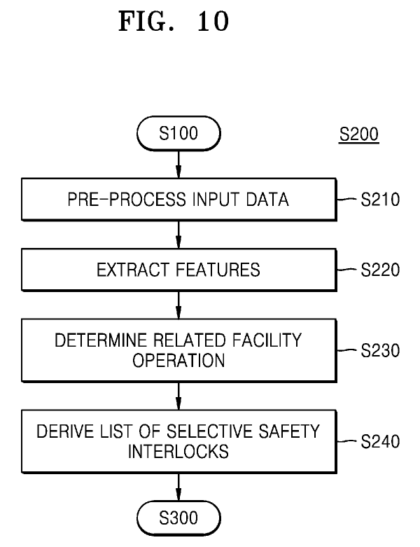

FIG. 9 is a flowchart illustrating a safety interlock control method according to an implementation. FIG. 10 is a flowchart showing a method of deriving a list of selective safety interlocks to be activated, according to an implementation. A description is given below with reference to FIGS. 1 to 8.

Referring to FIGS. 9 and 10, first, input data may be received (S100). The input data may include user log data, repair facility change management data for the semiconductor facility AP, and/or log data of the semiconductor facility AP.

Subsequently, the list of selective safety interlocks to be activated may be derived (S200). First, the input data that has been input in operation S100 may be pre-processed (S210). In an implementation, tokenization, stop-word removal, stemming, and/or normalization may be performed on the input data in operation S210.

In some implementations, text may be converted into structured information. In an implementation, the natural language analysis results on the input data may be generated by performing at least some of the plurality of unit analysis processes, such as semantic role labeling, morphological analysis, syntactic analysis, named entity analysis, filtering analysis, intent classification, and domain analysis.

After the input data is pre-processed (S210), features may be extracted (S220). The features may be extracted from the input data that has been pre-processed in operation S220. For example, the input data may be embedded based on deep learning. For example, the features may be extracted by using a pre-trained language model. For example, the language model may include a transformer-based language model. However, the present disclosure is not limited thereto, and the language model may include various types of language models. In another implementation, the features may be extracted by generating a word frequency-based sparse vector, or the features may be extracted on the basis of a distributed representation-based embedding technique (e.g., word2vec, glove, fasttext, etc.).

Subsequently, a semiconductor facility operation related to the input data may be determined (S230). Operation S230 may be performed based on the features extracted in operation S220. In an implementation, which facility operation corresponds to input data may be determined in a rule-based method. Operation S230 may be performed based on the first input data in the form of natural language and/or the second input data in the form of non-natural language.

Subsequently, the list of selective safety interlocks corresponding to the input data may be derived (S240). The list of selective safety interlocks that are required to be activated in response to the semiconductor facility operation determined in operation S230 may be derived. In an implementation, the selective safety interlock corresponding to the input data may be derived in a rule-based method.

Subsequently, whether the list of selective safety interlocks generated in operation S200 has been activated may be determined (S300). Operation S300 may be determined by the sensing data of each of the main sensor and the additional sensor in the semiconductor facility AP. When the sensing data of each of the main sensor and/or the additional sensor is within a preset range, it may be determined that the safety interlock has been performed. On the other hand, when the sensing data of the main sensor and/or the additional sensor is outside the preset range, it may be determined that the safety interlock has not been performed.

In an implementation, whether the list of safety interlocks is activated (or executed) may be determined based on the first sensing data of the main sensor and the second sensing data of the additional sensor. For example, whether or not to activate the list of safety interlocks corresponding to the main sensor may be determined based on whether the first sensing data of the main sensor is normal or abnormal. In another example, even if the first sensing data is normal, when the second sensing data is in an abnormal range, it may be determined that the list of safety interlocks has not been activated. Therefore, even if the main sensor is defective, whether the safety interlock is activated may be accurately determined.

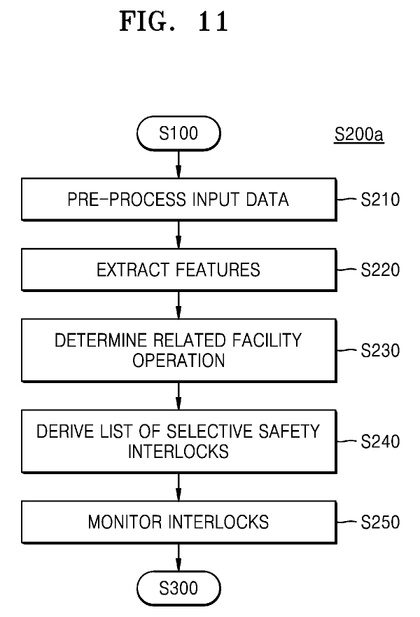

FIG. 11 is a flowchart showing a method of deriving a list of selective safety interlocks to be activated, according to an implementation. A description is given below with reference to FIGS. 1 to 10.

The method of deriving a list of selective safety interlocks (S200a) in FIG. 11 may be substantially the same as the method of deriving the list of selective safety interlocks (S200) in FIG. 10, except that the method in FIG. 11 may further include monitoring interlocks (S250). Therefore, the description focuses on the monitoring of interlocks (S250).

Referring to FIG. 11, in the monitoring of interlocks (S250), if there is a safety interlock that has not been activated for a certain period of time, the safety interlock may be activated for testing. The certain period of time may represent a preset period of time. Therefore, whether the safety interlock is activated may be easily determined. In operation S250, whether the safety interlock is activated may be determined based on the sensing data from each of the main sensor and/or additional sensor corresponding to the safety interlock.

In some implementations, operation S250 may include performing self-diagnostics on the safety interlock control method. In an implementation, whether the safety interlock control method may include a defect may be determined by logic. In an implementation, when the safety interlock system may include an unresolved problem for a certain period of time, the safety interlock system may be determined as defective. Also, the unresolved problems in the safety interlock control method may be identified, and these problems may be resolved.

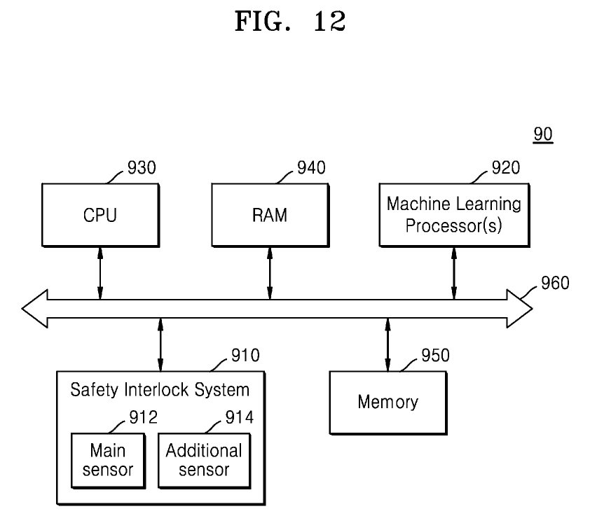

FIG. 12 is a block diagram showing a safety interlock control system according to an implementation. A description is given below with reference to FIGS. 1 to 11.

Referring to FIG. 12, a safety interlock control system 90 may analyze input data by using machine learning and derive a list of selective safety interlocks corresponding to the input data. The safety interlock control system 90 may include a safety interlock system 910, a machine learning processor 920, a central processing unit (CPU) 930, random access memory (RAM) 940, memory 950, and a bus 960.

According to implementations, the safety interlock control system 90 may include other general-purpose components in addition to the components shown in FIG. 12. For example, the safety interlock control system 90 may further include an input/output module, a security module, a power control device, etc., and may also further include various types of processors. Also, according to an implementation, at least one of the components in FIG. 12 may be omitted from the safety interlock control system 90. The components of the safety interlock control system 90 may communicate with each other via the bus 960.

The safety interlock system 910 may be configured to sense whether the safety interlock is activated. The safety interlock system 910 may include a main sensor 912 and an additional sensor 914. The main sensor 912 may represent a sensor that may directly determine whether the safety interlock is activated. For example, when the safety interlock relates to the opening and closing of the chamber door, the main sensor 912 of the safety interlock may include an opening/closing sensor of the chamber door. The additional sensor 914 may include a sensor that may indirectly determine whether the safety interlock is activated. In some implementations, although the main purpose of the additional sensor 914 is to manage process quality, the additional sensor 914 may also provide data for assisting the safety interlock.

For example, when the safety interlock relates to the opening and closing of the chamber door, the additional sensor 914 of the safety interlock may include a pressure sensor, a temperature sensor, a voltage sensor, and/or a flow rate sensor inside the chamber. Changes in pressure, temperature, voltage, and/or flow rate inside the chamber may be sensed by the additional sensor 914, and the amount of changes may be used as additional sensor data for the safety interlock.

The machine learning processor 920 may train (or learn) a machine learning model or analyze input data by using the machine learning model to infer information included in the input data. The machine learning processor 920 may determine conditions on the basis of the inferred information or control configurations of mounted electronic devices.

The machine learning processor 920 may be provided as a neural network operation accelerator, a coprocessor, a digital signal processor (DSP), an application specific integrated circuit (ASIC), a field-programmable gate array (FPGA), a graphics processing unit (GPU), a neural processing unit (NPU), a tensor processing unit (TPU), and a multi-processor system-on-chip (MPSoC).

In an implementation, the machine learning processor 920 may perform a text mining algorithm. However, the types of machine learning algorithms are not limited to the examples described above. For example, the machine learning processor 920 may perform machine learning algorithms, such as embedding, linear discriminant analysis (LDA), autoencoder, and t-distributed stochastic neighbor embedding (t-SNE).

The machine learning processor 920 may receive input data. The machine learning processor 920 may perform text mining on the pre-processed natural language input data and derive the list of selective safety interlocks corresponding to the input data. Also, the machine learning processor 920 may derive the list of selective safety interlocks based on the pre-processed non-natural language input data. In some implementations, the machine learning processor 920 may learn bypassed safety interlock patterns, based on the input data and output data (whether the safety interlock is bypassed).

In another implementation, the machine learning processor 920 may perform neural network algorithms, based on an artificial neural network (ANN), a convolution neural network (CNN), a region with convolution neural network (R-CNN), a convolution neural network (3D CNN), a region proposal network (RPN), a recurrent neural network (RNN), a generative adversarial network (GAN), a self-attention generative adversarial network (SAGAN), a stacking-based deep neural network (S-DNN), a state-space dynamic neural network (S-SDNN), a deconvolution network, a deep belief network (DBN), a restricted Boltzman machine (RBM), a fully convolutional network, a long short-term memory (LSTM) network, a classification network, a plain residual network, a dense network, a hierarchical pyramid network, a region-based fully convolution networks (RFCN), a single shot multibox (SSD), you only look once (YOLO), a transformer network, and/or a vision transformer network. However, the types of neural network models are not limited to the examples described above.

The CPU 930 may control all operations of the safety interlock system 910. The CPU 930 may include a single processor core (a single core) or a plurality of processor cores (a multi-core). The CPU 930 may process or execute programs and/or data stored in a storage region, such as the memory 950, by using the RAM 940.

For example, the CPU 930 may execute an application program and control the machine learning processor 920 to perform neural network-based tasks required by the execution of the application program.

The memory 950 may include at least one of volatile memory and non-volatile memory. The non-volatile memory may include read only memory (ROM), programmable ROM (PROM), electrically programmable ROM (EPROM), electrically erasable and programmable ROM (EEPROM), flash memory, etc. The volatile memory may include dynamic RAM (DRAM), static RAM (SRAM), synchronous DRAM (SDRAM), phase-change RAM (PRAM), magnetic RAM (MRAM), resistive RAM (RRAM), ferroelectric RAM (FeRAM), etc. In an implementation, the memory 950 may include at least one of a hard disk drive (HDD), a solid state drive (SSD), a compact flash (CF) card, a secure digital (SD) card, a micro secure digital (Micro-SD) card, a mini secure digital (Mini-SD) card, an extreme digital (xD) card, and a memory stick.

According to another aspect of the present disclosure, there is provided a safety interlock control method including receiving input data including data in a form of natural language, matching a list of selective safety interlocks to be activated to a list of standard interlocks by using a text mining algorithm, based on the input data, determining whether the list of selective safety interlocks is activated, and warning a user of a list of bypassed selective interlocks that are not activated.

The input data may include at least one of facility operation log data and facility change management log data created by the user.

The input data may include facility change management data and log data generated by the facility.

The matching of the list of selective safety interlock may be performed based on each of first input data in a form of natural language and second input data in a form of non-natural language.

The matching of the list of selective safety interlocks may be performed by a rule-based algorithm.

The matching of the list of selective safety interlocks may include determining a facility operation corresponding to the input data and deriving the list of selective safety interlocks corresponding to the facility operation.

The determining of whether the selective safety interlocks are activated may be performed based on sensing data values from each of a main sensor capable of directly identifying whether safety interlocks of a semiconductor facility are activated and an additional sensor capable of indirectly identifying whether the safety interlocks of the semiconductor facility are activated.

In the determining of whether the selective safety interlock are activated, even if first sensing data of the main sensor falls within a normal range or the first sensing data of the main sensor is missing, it may be determined that the selective safety interlock are not activated when second sensing data of the additional sensor falls within an abnormal range.

The additional sensor may be configured to sense at least one of the pressure, temperature, voltage, and flow rate of the semiconductor facility.

The safety interlock control method may further include a safety interlock monitoring operation of activating a safety interlock that has not been activated for a certain period of time to test a safety interlock system.

In some implementations, all functions of the components of the safety interlock control systems (e.g., safety interlock control systems 1, 2, 90) may be performed by one or more processors. In some implementations, all of the functions of the components of the safety interlock control systems may be performed by a single processor. In other implementations, the functions of the components of the safety interlock control systems may be distributed among multiple processors (e.g., one processor performs a subset of the functions of the components of the safety interlock control systems while one or more other processors perform the remaining functions of the components of the safety interlock control systems.)

All of the disclosed methods and procedures described in the present disclosure can be implemented, at least in part, using one or more computer programs or components. These components may be provided as a series of computer instructions on any conventional computer readable medium or machine readable medium, including volatile and non-volatile memory, such as RAM, ROM, flash memory, magnetic or optical disks, optical memory, or other storage media. The instructions may be provided as software or firmware, and may be implemented in whole or in part in hardware components such as ASICs, FPGAs, DSPs, or any other similar devices. The instructions may be configured to be executed by one or more processors or other hardware components which, when executing the series of computer instructions, perform or facilitate the performance of all or part of the disclosed methods and procedures.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A safety interlock control system comprising:
a user interface configured to receive, from a user, input data comprising data in a form of natural language and to transmit a response to the user; and
an interlock manager configured to perform a text mining algorithm on the input data to derive a list of selective safety interlocks corresponding to the input data, and to transmit a warning to the user about a list of bypassed selective safety interlocks that are not activated,
wherein the interlock manager comprises:
an interlock matcher configured to match the list of selective safety interlocks corresponding to the input data;
an interlock event analyzer configured to identify whether the matched list of selective safety interlocks is activated; and
an interlock result integrator configured to transmit, to the user, the list of bypassed selective safety interlocks that are not activated, via the user interface.

2. The safety interlock control system of claim 1, wherein the interlock matcher is configured to match the list of selective safety interlocks corresponding to the input data based on a rule-based algorithm.

3. The safety interlock control system of claim 1, wherein the interlock manager comprises a log analyzer configured to match a facility operation corresponding to the input data, based on the input data.

4. The safety interlock control system of claim 3, wherein the log analyzer is configured to match the facility operation corresponding to the input data based on a rule-based algorithm.

5. The safety interlock control system of claim 1, wherein the input data comprises data in a form of non-natural language.

6. The safety interlock control system of claim 1, wherein the interlock manager comprises a feature extractor configured to extract features from the input data.

7. The safety interlock control system of claim 1, wherein the interlock event analyzer is configured to identify whether the list of selective safety interlocks is activated based on sensing data values from a sensor in a semiconductor facility.

8. A safety interlock control system comprising:
a user interface configured to receive, from a user, input data comprising data in a form of natural language and to transmit a response to the user; and
an interlock manager configured to perform a text mining algorithm on the input data to derive a list of selective safety interlocks corresponding to the input data, identify whether the list of selective safety interlocks is activated, and transmit a warning to the user about a list of bypassed selective safety interlocks that are not activated,
wherein the interlock manager comprises:
a log analyzer configured to match a facility operation corresponding to the input data;
an interlock matcher configured to match the list of selective safety interlocks corresponding to the facility operation;
an interlock event analyzer configured to identify whether the matched list of selective safety interlocks is activated; and
an interlock result integrator configured to transmit, to the user, the list of bypassed selective safety interlocks that are not activated, via the user interface.

9. The safety interlock control system of claim 8, wherein the interlock event analyzer is connected to a main sensor configured to directly identify whether a safety interlock of a semiconductor facility is activated and an additional sensor configured to indirectly identify whether the safety interlock of the semiconductor facility is activated.

10. The safety interlock control system of claim 9, wherein the interlock event analyzer is configured to determine that the safety interlock is not activated based on sensing data from the additional sensor being within an abnormal range despite sensing data from the main sensor being within a normal range.

11. The safety interlock control system of claim 9, wherein the additional sensor comprises at least one of a pressure sensor, a temperature sensor, a voltage sensor, or a flow rate sensor.

12. The safety interlock control system of claim 8, wherein the interlock matcher is configured to match the facility operation and a standard interlock list corresponding to the facility operation.

13. The safety interlock control system of claim 8, comprising an interlock monitor configured to determine whether a safety interlock system is normal or defective.

14. The safety interlock control system of claim 13, wherein the interlock monitor comprises a watchdog timer configured to activate a safety interlock that has not been activated for a certain period of time to determine whether the safety interlock is defective.

15. The safety interlock control system of claim 14, wherein the watchdog timer is configured to determine whether the safety interlock is defective based on sensing data from each of a main sensor and an additional sensor of a semiconductor facility.

16. The safety interlock control system of claim 8, comprising a statistical analyzer configured to be trained based on the input data and output data corresponding to the input data, thereby inferring a relationship between the input data and the output data.

17. A safety interlock control system comprising:
a user interface configured to receive, from a user, input data comprising data in a form of natural language and to transmit a response to the user;
an interlock manager configured to perform a text mining algorithm on the input data to derive a list of selective safety interlocks corresponding to the input data, identify whether the list of selective safety interlocks is activated, and transmit a warning to the user about a list of bypassed selective safety interlocks that are not activated; and
a statistical analyzer configured to infer a safety interlock bypass pattern based on the input data and the list of bypassed selective safety interlocks,
wherein the interlock manager comprises:
a log analyzer configured to match a semiconductor facility operation corresponding to the input data;
an interlock matcher configured to match the list of selective safety interlocks corresponding to the semiconductor facility operation and required to be activated;
an interlock event analyzer configured to identify whether the matched list of selective safety interlocks is activated; and
an interlock result integrator configured to transmit, to the user, the list of bypassed selective safety interlocks that are not activated, via the user interface, and
wherein the log analyzer comprises:
a pre-processor configured to pre-process the input data;
a feature extractor configured to extract features from the pre-processed input data; and
an analyzer configured to determine a facility operation corresponding to the input data based on the extracted features, and
wherein the interlock event analyzer is configured to determine whether the selective safety interlock is activated based on sensing data from a main sensor configured to directly identify whether a safety interlock of a semiconductor facility is activated, and
wherein the interlock result integrator is configured to:
transmit a warning to the user about the list of bypassed selective safety interlocks via the user interface; and
store the list of bypassed selective safety interlocks and the input data corresponding to the list of bypassed selective safety interlocks in a database.

18. The safety interlock control system of claim 17, wherein the feature extractor is configured to extract the features based on a text mining algorithm.

19. The safety interlock control system of claim 17, wherein the analyzer is configured to determine the facility operation corresponding to the input data based on a rule-based algorithm.

20. The safety interlock control system of claim 17, wherein the interlock event analyzer is configured to determine whether the safety interlock is activated based on sensing data from each of the main sensor and an additional sensor configured to indirectly identify whether the safety interlock of the semiconductor facility is activated.
